(19) United States
(12) Patent Application Publication
(10) Pub. No.: US 2015/0162159 A1
(43) Pub. Date: Jun. 11, 2015

(54) BEARING ARRANGEMENT FOR ROTATABLY MOUNTING AN ELECTRODE AND ELECTRODE ARRANGEMENT

(71) Applicant: VON ARDENNE GmbH, Dresden (DE)

(72) Inventors: Hans-Juergen HEINRICH, Grossroehrsdorf (DE); Gerit STUDE, Dresden (DE); Goetz GROSSER, Dresden (DE)

(21) Appl. No.: 14/555,724

(22) Filed: Nov. 28, 2014

(30) Foreign Application Priority Data
Dec. 5, 2013 (DE) 10 2013 113 562.5

(51) Int. Cl. H01J 23/05; F16C 33/74; H01J 37/34; F16C 41/00; H01J 23/00; F16C 17/02; F16C 37/00

(52) U.S. Cl. CPC H01J 23/05; F16C 17/02; F16C 33/74; F16C 33/741; F16C 37/00; F16C 41/002; H01J 23/005; H01J 37/3405

(57) ABSTRACT

In various embodiments, a bearing arrangement for rotatably mounting an electrode is provided. The bearing arrangement may include an outer sleeve, which is insertable into a housing for mounting a rotatable electrode; an inner element, which is received coaxially in the outer sleeve and is mounted by a first bearing and a second bearing so as to be rotatable in relation to the outer sleeve, wherein the bearings are spaced apart from one another in the axial direction; and an electrically conductive contact structure, which is positioned alongside at least one of the first bearing or the second bearing and which makes electrical contact with the inner element.

### CROSS-REFERENCE TO RELATED APPLICATION

This application claims priority to German Patent Application Serial No. 10 2013 113 562.5, which was filed Dec. 5, 2013, and is incorporated herein by reference in its entirety.

### TECHNICAL FIELD

Various embodiments relate generally to a bearing arrangement for rotatably mounting an electrode and to an electrode arrangement.

### BACKGROUND

In general, electrodes can be used in coating technology for various processes and/or pre-treatments. By way of example, in a sputtering process (cathode atomization) use can be made of a tubular target (a tubular cathode), from which the coating material can be sputtered, or which is atomized. In general, a tubular electrode (cathode and/or anode) can rotate during the processing. This can make it possible to achieve, for example, a process with long-term stability, e.g. a coating process with long-term stability. In magnetron sputtering (magnetic field assisted cathode atomization), use can be made, for example, of a tubular cathode which rotates during the sputtering process, with a magnet arrangement being arranged within the tubular cathode in order to influence plasma formation and therefore inter alia the sputtering rate and/or other process parameters of the sputtering process. Furthermore, a magnetron arrangement can also have a plurality of tubular cathodes (tubular targets), for example in the case of what is termed a rotatable dual magnetron.

### SUMMARY

In various embodiments, a bearing arrangement for rotatably mounting an electrode is provided. The bearing arrangement may include an outer sleeve, which is insertable into a housing for mounting a rotatable electrode; an inner element, which is received coaxially in the outer sleeve and is mounted by a first bearing and a second bearing so as to be rotatable in relation to the outer sleeve, wherein the bearings are spaced apart from one another in the axial direction; and an electrically conductive contact structure, which is positioned alongside at least one of the first bearing or the second bearing and which makes electrical contact with the inner element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a bearing arrangement, according to various embodiments;

FIG. 1B shows a schematic side view of a bearing arrangement, according to various embodiments;

FIGS. 1C to 1F each show a schematic cross-sectional view of a bearing arrangement, according to various embodiments;

FIGS. 2A and 2B each show a schematic cross-sectional view of an electrode arrangement, according to various embodiments;

FIGS. 3A and 3B each show a schematic cross-sectional view of a housing and of a bearing arrangement, separated from one another and put together, according to various embodiments;

FIG. 4A shows an electrode arrangement in a schematic exploded illustration, according to various embodiments;

FIG. 4B shows an electrode arrangement in a schematic cross-sectional view, according to various embodiments;

FIG. 5A shows an electrode arrangement in a schematic exploded illustration, according to various embodiments;

FIG. 5B shows an electrode arrangement in a schematic cross-sectional view, according to various embodiments; and

FIG. 6 shows a processing apparatus with an electrode arrangement in a schematic view, according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In the following detailed description, reference is made to the accompanying drawings, which form part of this description and in which specific embodiments in which the invention can be implemented are shown for purposes of illustration. In this respect, directional terminology such as for instance “up”, “down”, “forward”, “backward”, “front”, “rear”, etc. is used with respect to the orientation of the figure(s) described. Since components of embodiments may be positioned in a number of different orientations, the directional terminology serves for the purposes of illustration and is not in any way restrictive. It goes without saying that other embodiments can be used and structural or logical changes may be made without departing from the scope of protection of the present invention. It goes without saying that the features of the various embodiments that are given by way of example and described herein can be combined with one another, unless specifically stated otherwise. The following detailed description should therefore not be understood in a restrictive sense, and the scope of protection of the present invention is defined by the appended claims.

In the context of this description, the terms “connected” and “coupled” are used for describing both a direct and an indirect connection and a direct or indirect coupling.

As described herein, an outer circumference can be understood to mean an outer circumferential surface or the outwardly delimiting surface of a body. Similarly, the inner circumference can be understood to mean an inner circumferential surface or the inwardly delimiting surface of a body.

One aspect of various embodiments can clearly be seen in the provision of a bearing arrangement for rotatably mounting an electrode; by way of example, a tubular target for a magnetron can be mechanically rotatably mounted by means of the bearing arrangement and electrically contact-connected, with the bearing arrangement making it possible to achieve a structure, for example, which enables simple maintenance and/or repair of the bearing arrangement and the wearing parts thereof. When considered illustratively, a tubular magnetron target can be coupled to what is termed a magnetron end block by means of the bearing arrangement in such a way that an energy supply (e.g. for providing a predefined electrical potential to the magnetron target), a cooling water supply (e.g. for cooling the tubular magnetron target and/or for cooling a magnet arrangement within the tubular magnetron target) and/or rotatable mounting of the tubular magnetron target (e.g. for homogeneously atomizing the surface of the tubular magnetron target) are made possible, and such that the bearing arrangement and/or the magnetron end block (the housing) are furthermore designed in such a manner that the bearing arrangement can be inserted into the magnetron end block in a removable manner, and that wearing parts of the bearing arrangement (e.g. sealing elements or bearings) can be replaced, without the bearing arrangement having to be removed from the magnetron end block.

Furthermore, it is possible for rotatably mounted electrodes to be utilized as anodes in what is termed an SAD (Spotless arc Activated Deposition) process, by means of which high-rate electron beam deposition can be realized.

According to various embodiments, provision is made of an electrode arrangement, having a bearing arrangement and a corresponding housing, which are designed in such a manner that the individual components of the bearing arrangement can be inserted or extracted successively along the axis of rotation (or such that the bearing arrangement can be assembled and/or disassembled successively along the axis of rotation), such that maintenance work and/or repairs can be carried out in a time-efficient and cost-efficient manner on the electrode arrangement (e.g. on a magnetron arrangement).

Furthermore, another aspect of various embodiments can clearly be seen in the fact that the housing is sealed off with respect to a vacuum by means of the bearing arrangement (e.g. such that an electrode coupled to the housing by means of the bearing arrangement can be operated in vacuum), and at the same time provision is made by means of the housing and of the bearing arrangement for cooling (e.g. water cooling or cooling based on a fluid) for an electrode coupled to the housing by means of the bearing arrangement.

According to various embodiments, provision is made of a bearing arrangement for mounting a rotatable electrode, wherein the bearing arrangement can have the following: an outer sleeve, which is insertable into a housing for mounting a rotatable electrode; an inner element, which is received coaxially in the outer sleeve and is mounted by means of a first bearing and a second bearing so as to be rotatable in relation to the outer sleeve, wherein the bearings are spaced apart from one another in the axial direction, and an electrically conductive contact structure, which is positioned between the first bearing and the second bearing and which makes electrical contact with the inner element. In this case, the inner element can be an inner sleeve, e.g. a hollow tube, or the inner element can have a cylindrical outer lateral surface and at least one passage opening in the axial direction. According to various embodiments, the first bearing and the second bearing can be spaced apart from one another.

According to various embodiments, the electrically conductive contact structure can have one or more clamping points for the fastening of a sliding contact or of a plurality of sliding contacts.

The bearing arrangement can furthermore have the following: a first receiving region, which is formed at a first axial end portion of the bearing arrangement between an inner circumference of the outer sleeve and an outer circumference of the inner element for receiving a first sealing element.

The bearing arrangement can furthermore have the following: a second receiving region, which is formed at a second axial end portion of the bearing arrangement between an inner circumference of the outer sleeve and an outer circumference of the inner element for receiving a second sealing element. In this case, the second end portion can be positioned opposite to the first end portion.

The bearing arrangement can furthermore have the following: a first sealing element inserted coaxially into the first receiving region of the bearing arrangement (in a removable manner) and/or a second sealing element inserted coaxially into the second receiving region of the bearing arrangement (in a removable manner).

Furthermore, a first distance between the outer circumference of the inner element and the inner circumference of the outer sleeve in the region between the first bearing and the second bearing can be smaller than a second distance between the outer circumference of the inner element and the inner circumference of the outer sleeve in the region of the first bearing and/or of the second bearing.

Furthermore, a third distance between the outer circumference of the inner element and the inner circumference of the outer sleeve in the region of the first receiving region and/or second receiving region can be greater than a second distance between the outer circumference of the inner element and the inner circumference of the outer sleeve in the region of the first bearing and/or of the second bearing.

Furthermore, the electrically conductive contact structure can have at least one sliding contact (or a plurality of sliding contacts, e.g. two, three, four or five sliding contacts, or more than five sliding contacts), which slides on the outer circumference of the inner element. In this case, the sliding contact can be designed in a manner electrically insulated from the outer sleeve, e.g. the electric current can be guided from the sliding contact through an electrically insulated passage hole in the outer sleeve to the outside. In other words, the electrical contact structure can be guided through the wall of the outer sleeve, e.g. at one point or at a plurality of points.

Illustratively, the inner element and the outer sleeve can be designed and arranged in relation to one another in such a manner that a plurality of regions are provided between the outer circumference of the inner element and the inner circumference of the outer sleeve, the distances between the outer circumference of the inner element and the inner circumference of the outer sleeve in the plurality of regions differing from one another. Therefore, for example, the bearings (the first bearing and the second bearing) can be inserted into the bearing arrangement from an axial direction and can be removed from the bearing arrangement along the axial direction. This makes it possible to easily maintain or repair the bearings and/or the electrical contact structure (e.g. a sliding contact). Furthermore, it is also possible, for example, for the sealing elements (the first sealing element and the second sealing element) to be inserted into the bearing arrangement from an axial direction and to be removed from the bearing arrangement along the axial direction. This makes it possible to easily maintain or repair the sealing elements. The bearings, the electrical contact structure and/or the sealing elements can be, for example, wearing parts of the bearing arrangement. In this case, the bearing arrangement can be designed in such a manner that the wearing parts can be assembled and disassembled from an axial direction, or that the wearing parts can be assembled and disassembled from opposite directions (both parallel to the axial direction).

Furthermore, the inner element can have an axial passage opening. In other words, the inner element can have a passage opening, a borehole or the like along the axial direction, such that, for example, cooling water can flow through the inner element. In this respect, for example, cooling water can flow from a housing (e.g. end block) through the bearing arrangement into an electrode (tubular cathode) coupled to the bearing arrangement and/or can flow from the electrode through the bearing arrangement to the housing.

Furthermore, the electrically conductive contact structure can extend through the outer sleeve and/or the outer sleeve can be electrically insulated from the electrically conductive contact structure.

Furthermore, the first bearing and the second bearing may include an electrically insulating material, such that the inner element is electrically insulated from the outer sleeve by means of the first bearing and the second bearing.

According to various embodiments, a bearing arrangement may have: an outer sleeve and an inner element inserted coaxially into the outer sleeve, wherein the outer sleeve and the inner element are arranged in such a manner that they can be rotated in relation to one another by means of rotary bearings arranged between the outer sleeve and the inner element, wherein the bearing arrangement is formed in such a manner that it can be inserted from one of its axial end portions into an end block of an electrode arrangement in a removable manner and can be coupled with its other axial end portion to a magnetron cathode; and wherein a sealing element is insertable into the bearing arrangement from in each case one of the free axial ends of the bearing arrangement in a removable manner, in such a manner that the space between the sealing elements is sealed off against the penetration of water and/or air.

According to various embodiments, an electrode arrangement may have the following: a housing for the mounting of a rotatable electrode, wherein the housing has a passage opening, which is formed for receiving a bearing arrangement (as described herein), wherein the passage opening defines an axial direction and the housing is designed in such a manner that the bearing arrangement is introducible coaxially into the passage opening (in a removable manner), such that the outer sleeve of the bearing arrangement is supported at least in certain portions on the housing. By way of example, the bearing arrangement can adjoin the housing (and therefore be supported) at least partially with the outer circumference of the outer sleeve and/or at least partially with an end face of the outer sleeve. By way of example, the electrode arrangement can be or have a magnetron arrangement, in which case the rotatable electrode can be a magnetron cathode or a target tube and the housing can be what is termed a magnetron end block. According to various embodiments, the electrode arrangement can furthermore have the following: a bearing arrangement inserted into the passage opening in a removable manner.

Furthermore, the passage opening of the housing and the bearing arrangement can be designed and arranged in relation to one another in such a manner that a first sealing element is insertable coaxially into the first receiving region of the bearing arrangement in a removable manner and/or that a second sealing element is insertable coaxially into the second receiving region of the bearing arrangement in a removable manner.

According to various embodiments, the electrode arrangement may furthermore have the following: a first sealing element inserted coaxially into the first receiving region of the bearing arrangement in a removable manner and/or a second sealing element inserted coaxially into the second receiving region of the bearing arrangement in a removable manner.

Furthermore, the first sealing element can be a vacuum seal, by means of which the first receiving region between the outer sleeve and the inner element is sealed off in a vacuum-tight manner. Furthermore, the second sealing element can be a fluid seal, by means of which the second receiving region between the outer sleeve and the inner element is sealed off in a fluid-tight manner.

Furthermore, the housing and the bearing arrangement can be designed and arranged in relation to one another in such a manner that the bearing arrangement and the first sealing element are fixable in relation to one another by means of a flange ring and/or that the bearing arrangement and the first sealing element are fixable on the housing by means of the flange ring.

Furthermore, the housing and the bearing arrangement can be designed and arranged in relation to one another in such a manner that the bearing arrangement and the second sealing element are fixable in relation to one another by means of a flange and/or that the bearing arrangement and the second sealing element are fixable on the housing by means of the flange.

According to various embodiments, the electrode arrangement can furthermore have the following: a flange ring which is connected to the housing and which fixes the bearing arrangement and the first sealing element in relation to one another and/or to the housing.

According to various embodiments, the electrode arrangement may furthermore have the following: a flange which is connected to the housing and which fixes the bearing arrangement and the second sealing element in relation to one another and/or to the housing.

Furthermore, the flange ring may be designed in such a manner that an end face of the inner element is accessible from the axial direction. Furthermore, the flange ring may be designed in such a manner that a free end portion of the inner element is accessible from the axial direction.

According to various embodiments, the axis of rotation of the bearing arrangement can define the axial direction. Furthermore, the passage hole of the housing can define the axial direction. Furthermore, the housing and the bearing arrangement can be designed in such a manner that the bearing arrangement can be inserted or is insertable coaxially into the passage hole of the housing.

Furthermore, the flange can have a cooling water guide, by means of which cooling water can be conducted through the flange towards the inner element. Furthermore, the flange can have a cooling water guide, by means of which cooling water can be carried away through the flange from the inner element.

According to various embodiments, the electrode arrangement may furthermore have the following: a coupling element for coupling an electrode to the inner element, wherein the coupling element is fastened to a first axial end portion of the inner element. The coupling element can be, for example, a clamp, to which the electrode can be clamped. Furthermore, the coupling element and the inner element can be designed in such a manner that the coupling element can be screwed onto the inner element.

According to various embodiments, a method for operating an electrode arrangement may include the following: the extraction and/or introduction along the axial direction of a rotatable bearing arrangement into a housing of an electrode arrangement for rotatably mounting an electrode.

According to various embodiments, a method for operating an electrode arrangement may include the following: the extraction and/or introduction of a first sealing element and/or of a second sealing element along the axial direction of a bearing arrangement inserted into a housing in a removable manner. Here, by way of example, the sealing elements can be extracted or introduced, while the bearing arrangement remains in the housing.

According to various embodiments, a bearing arrangement described herein can be used to rotatably mount a tubular electrode (e.g. a magnetron cathode or a magnetron target) of an electrode arrangement and to make electrical contact therewith.

According to various embodiments, a bearing arrangement described herein can be used to fasten a magnetron tube to a magnetron end block.

Furthermore, the electrode arrangement can be designed in a vacuum environment (e.g. partially within a vacuum chamber, processing apparatus or vacuum processing apparatus). In other words, the bearing arrangement can be used for the rotatable mounting and electrical contact-connection of a tubular electrode in a vacuum treatment plant.

In general, coating systems can be designed in such a manner that, for example, it is possible to ensure a long production free from interruption and also a high sputtering power and/or that it is possible to use materials with a high specific weight, for example molybdenum. Accordingly, it is possible to use tubular electrodes (tubular targets or tubular cathodes) in sputtering systems, in which a tubular electrode is intended to provide as far as possible a large quantity of material to be atomized. Therefore, a tubular electrode can have, for example, a large length (e.g. with a length of up to approximately 4 m or with a length of more than approximately 4 m) and/or a large diameter (e.g. with a diameter of up to approximately 30 cm (e.g. approximately 13 cm to approximately 18 cm) or with a diameter of more than approximately 30 cm), as a result of which these tubular electrodes can have a high weight.

These tubular electrodes can be mounted axially at their ends, e.g. by means of a bearing arrangement and a housing (what is termed an end block), and can be rotated continuously during processing (e.g. during a sputtering process or during an SAD process). In this case, the mounting of the tubular electrodes may require the stable vacuum sealing of the rotary leadthrough to maintain the technological processes.

Furthermore, the processing may give rise to heat, which has to be dissipated, for example, from the tubular electrode, e.g. by means of a fluid coolant and a correspondingly designed cooling apparatus. The cooling can be realized, for example, by means of cooling water in the interior of the tubular electrodes (water can flow through the tubular electrode, for example), it being possible for the replacement of the coolant which is required here (cooling circuit) to be effected by means of the bearing arrangement.

According to various embodiments, an electrical contact structure (e.g. sliding electrical contacts) can be used to transfer the electrical energy required for processing to the tubular electrode, the electrical contact structure making it possible to achieve a service life of the bearing arrangement of several years.

Furthermore, in the case of electrophysical processes carried out in vacuum, it may be necessary to provide a stable gas pressure within the vacuum chamber, as a result of which high demands can be placed on the bearing arrangement and the corresponding housing with respect to the tightness and cleanliness.

According to various embodiments, provision is made of a bearing arrangement and a corresponding housing, which enable both a long service life and also simple accessibility for assembly to the wearing parts of the bearing arrangement. Furthermore, a vacuum seal and a cooling water guide are implemented.

By way of example, on account of the structure provided, the seals (or sealing elements) of the bearing arrangement can be replaced (or maintained or repaired) without disassembling the complete bearing arrangement. Furthermore, the bearings (e.g. rolling bearings) of the bearing arrangement can be lubricated more easily, as a result of which, for example, it is possible to achieve a longer service life of the bearings.

According to various embodiments, provision is made, for example, of an electrode arrangement having a housing and a bearing arrangement (or a rotary leadthrough), in which it is possible to easily access components which are to be replaced within the bearing arrangement and the bearing arrangement furthermore has a long service life.

When considered illustratively, provision can be made of a rotary leadthrough having a modular design (having a bearing arrangement and a housing), wherein, for example, a magnetron can be mounted such that it can be rotated by means of the rotary leadthrough in a vacuum chamber, wherein a replaceable bearing arrangement having an integrated sliding contact (or a plurality of integrated sliding contacts) and separate seals (sealing elements) can be incorporated in a housing, and wherein the accessibility to the seals for assembly can be realized by way of two removable (unscrewable) flanges. Here, the load-bearing bearing arrangement can consist of an inner hollow shaft (an inner element), an external sleeve (an outer sleeve), at least two electrically insulated rolling bearings (a first bearing and a second bearing) and the sliding contacts enclosed therebetween (an electrical contact structure). Furthermore, the seal can be located upstream of the rolling bearing in each case in the axial direction (in both parallel axial directions). Furthermore, it is possible, for example, for the bearings and seals to be relubricated without separate removal from the rotary leadthrough.

According to various embodiments, raceways of the rolling bodies of the rolling bearings can be integrated in the inner hollow shaft or in the external sleeve or in both. Furthermore, the inner hollow shaft can have receptacles for seal wearing sleeves (sealing elements). Furthermore, the external sleeve can have clamping points for fastening the sliding contacts.

Illustratively, the service life of the sliding contacts in connection with the service life of the rolling mounting ensured by means of relubrication defines the overall service life of the rotary leadthrough. By way of example, the bearing arrangement can be replaced without disassembling the rotary leadthrough from a magnetron cover, which holds the rotary leadthrough, for example. The rotary leadthrough can be designed in such a manner that integrated relubrication of the seals and bearings is possible and therefore optimum service lives are achieved. Maintenance work is possible, for example, without disassembling the electrode arrangement from the vacuum chamber and/or without disassembling the magnetron end block from the magnetron cover, since the seals are replaceable separately along the axial direction. It is therefore possible to realize short downtimes.

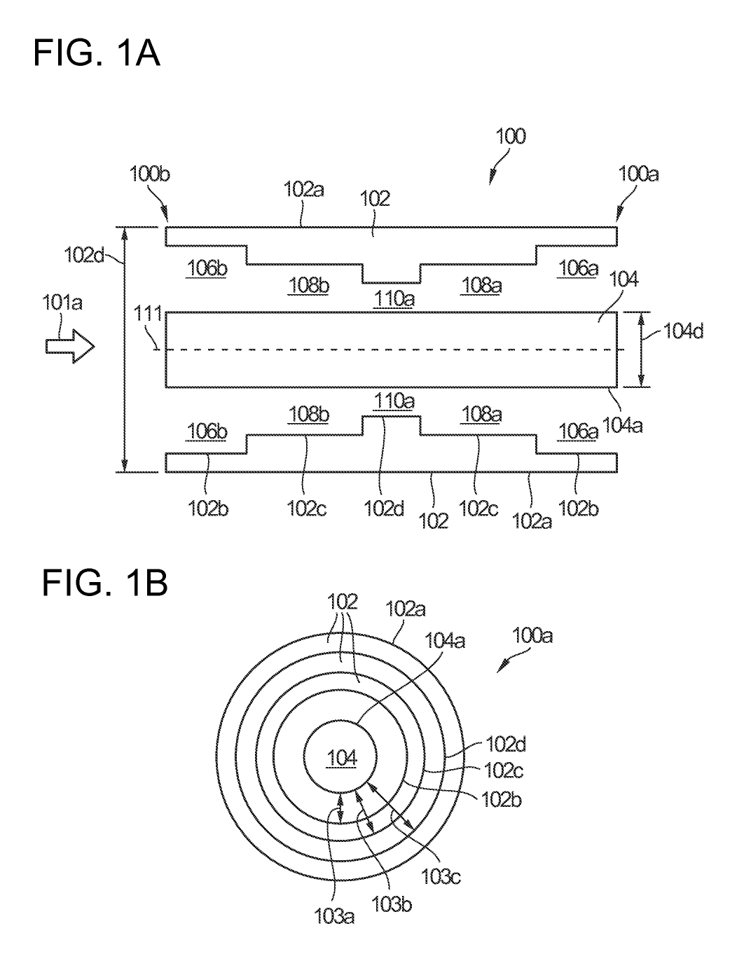

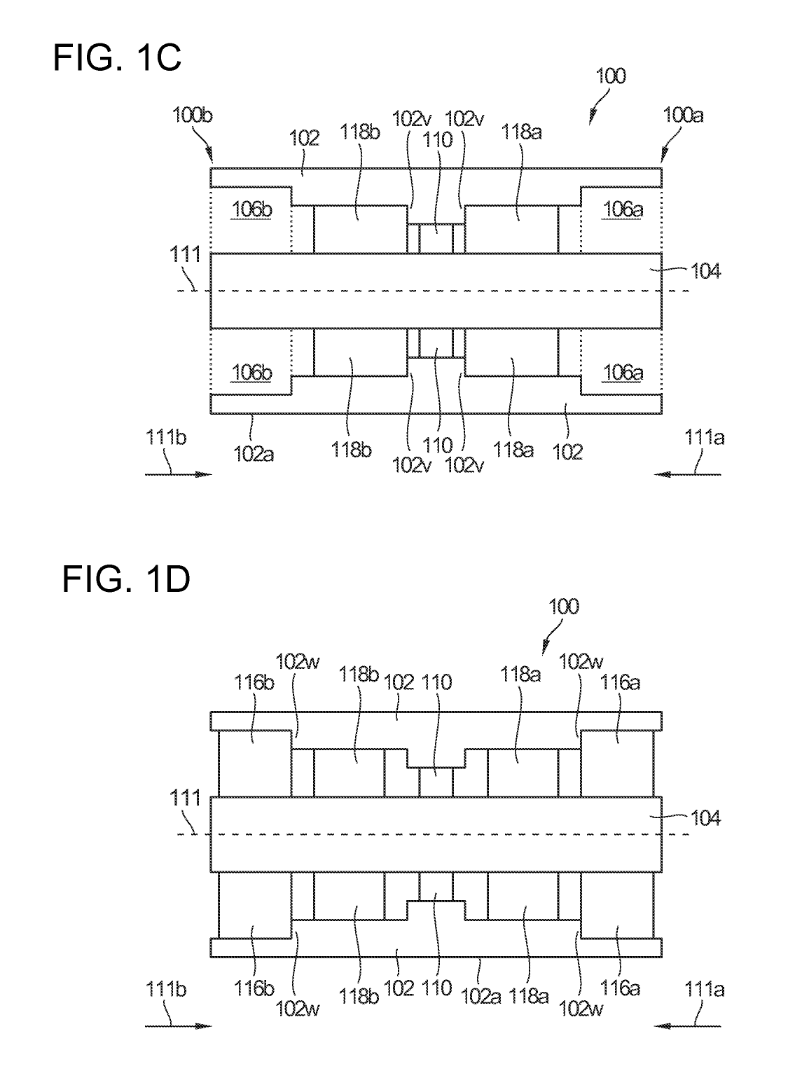

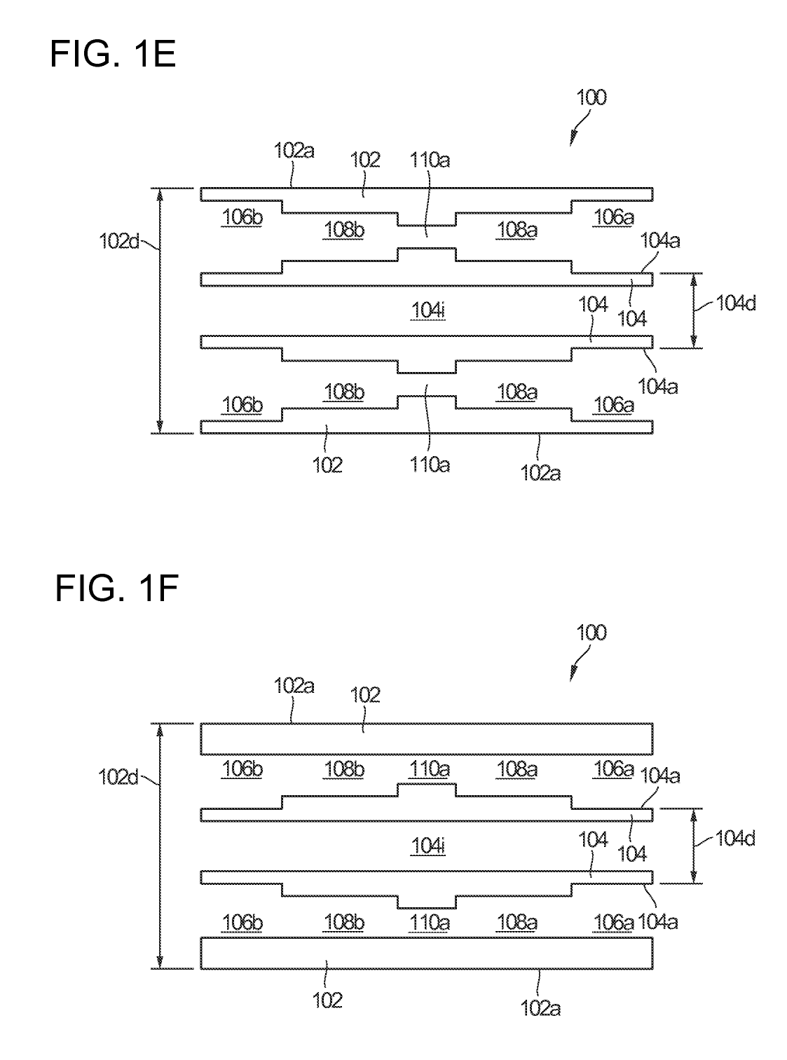

FIGS. 1A-1B show an arrangement of an inner element 104 in relation to an outer sleeve 102 of a bearing arrangement 100, according to various embodiments. FIG. 1A shows an arrangement of inner element 104 in relation to an outer sleeve 102 of a bearing arrangement 100 in a schematic cross-sectional view, according to various embodiments. FIG. 1B shows an arrangement of inner element 104 in relation to an outer sleeve 102 of a bearing arrangement 100 in a schematic side view from the direction 101a (or, on account of possible symmetry, also from the opposite direction), according to various embodiments.

The inner element 104 and the outer sleeve 102 can be designed and/or arranged in relation to one another in such a manner that various regions 106a, 106b, 108a, 108b, 110a for receiving further components of the bearing arrangement 100 are provided between the outer circumference 104a of the inner element 104 and an inner circumference 102b, 102c, 102d of the outer sleeve 102. According to various embodiments, the bearing arrangement 100 can be rotationally symmetrical with respect to an axis 111 (the axial direction). Furthermore, the inner element 104 and the outer sleeve 102 can be designed in such a manner that further components (e.g. bearings or seals) can be inserted successively into the bearing arrangement 100. Furthermore, the inner element 104 and the outer sleeve 102 can be designed in such a manner that the inner element 104 can be mounted rotatably in relation to the outer sleeve 102.

The outer sleeve 102 can have a cylindrical outer shape 102a, e.g. with a constant external diameter 102d and a circular cross section, or can be based on a circular area (cf. FIG. 1B). In other words, the outer sleeve 102 can have a cylindrical lateral surface 102a as the outer delimitation. Alternatively, the outer sleeve 102 can have at least on the outside a different shape, for example a shape of angular cross section perpendicular to the axial direction 111 or an oval shape or the like, where in this case the housing, which is intended to receive the bearing arrangement 100 or into which the bearing arrangement 100 is intended to be inserted, can be adapted appropriately.

A plurality of regions 106a, 106b, 108a, 108b, 110a for receiving electrical contacts, mechanical bearings or seals can extend between the inner element 104 and the outer sleeve 102. The inner surfaces 102b, 102c, 102d of the outer sleeve 102 can each be cylindrical surfaces in the corresponding regions 106a, 106b, 108a, 108b, 110a, e.g. each with a constant diameter and a circular cross section, or can be based on a circular area (cf. FIG. 1B).

The inner element 104 can likewise have a cylindrical outer shape 104a, e.g. with a constant external diameter 104d and a circular cross section, or can be based on a circular area (cf. FIG. 1B). In other words, the inner element 104 can have a cylindrical lateral surface 104a as the outer delimitation.

When considered illustratively, the outer sleeve 102 can be designed on the inside in such a manner that various distances 103a, 103b, 103c between the outer circumference 104a of the inner element 104 and the respective inner circumference of the outer sleeve 102 are provided in the regions 106a, 106b, 108a, 108b, 110a.

Alternatively, by way of example, the inner element 104 can also be designed on the outside in such a manner that various distances 103a, 103b, 103c between the inner circumference of the outer sleeve 102 and the respective outer circumference of the inner element 104 are provided in the regions 106a, 106b, 108a, 108b, 110a (not shown), or both the inner element 104 and the outer sleeve 102 can be designed in such a manner that various distances 103a, 103b, 103c between the respective inner circumference of the outer sleeve 102 and the respective outer circumference of the inner element 104 are provided in the regions 106a, 106b, 108a, 108b, 110a (cf. FIG. 1E).

According to various embodiments, the distance 103a between the inner circumference 102d of the outer sleeve 102 and the outer circumference 104a of the inner element 104 in the region 110a (in which, for example, an electrical contact structure can be accommodated) can be smaller than, for example, the distance 103b between the inner circumference 102c of the outer sleeve 102 and the outer circumference 104a of the inner element 104 in the region 108a and/or the region 108b (in which, for example, a bearing can be accommodated respectively).

According to various embodiments, the distance 103a between the inner circumference 102d of the outer sleeve 102 and the outer circumference 104a of the inner element 104 in the region 110a (in which, for example, an electrical contact structure can be accommodated) can be smaller than, for example, the distance 103c between the inner circumference 102b of the outer sleeve 102 and the outer circumference 104a of the inner element 104 in the region 106a and/or the region 106b (in which, for example, a seal can be accommodated respectively).

According to various embodiments, the distance 103b between the inner circumference 102c of the outer sleeve 102 and the outer circumference 104a of the inner element 104 in the region 108a and/or the region 108b (in which, for example, a bearing can be accommodated respectively) can be smaller than, for example, the distance 103c between the inner circumference 102b of the outer sleeve 102 and the outer circumference 104a of the inner element 104 in the region 106a and/or the region 106b (in which, for example, a seal can be accommodated respectively).

When considered illustratively, the inner element 104 and the outer sleeve 102 can be provided in such a manner that the regions 106a, 106b, 108a, 108b, 110a are each accessible from the axial direction 111, such that, for example, the bearings and/or the seals are insertable in succession into the corresponding regions in a removable manner, i.e. such that, for example, the bearings and/or the seals can be introduced between the outer sleeve 102 and the inner element 104 in the axial direction 111 or can be extracted from the bearing arrangement 100 in the axial direction 111. When considered illustratively, the inner element 104 and/or the outer sleeve 102 can have a stepped design in such a manner that the wearing parts can be introduced or inserted in a removable manner between the outer sleeve 102 and the outer sleeve 102 along the axial direction 111.

As shown in FIGS. 1A-1B, the bearing arrangement 100 can have, for example, a first end 100a and a second end 100b. The bearing arrangement 100 can have a symmetrical design between the ends 100a and 100b, as is shown by way of example, or alternatively the bearing arrangement 100 can have an asymmetrical design between the ends 100a and 100b. The bearing arrangement 100 can have a rotationally symmetrical design perpendicular to the axial direction 111, and therefore the inner element 104 can rotate in the outer sleeve 102.

According to various embodiments, the inner element 104 can have an external diameter in a range of several centimetres, for example in a range of approximately 3 cm to approximately 10 cm. Furthermore, the inner element 104 can have an external diameter in a range of several centimetres to several tens of centimetres, for example in a range of approximately 6 cm to approximately 20 cm, e.g. in a range of approximately 10 cm to approximately 30 cm.

As is shown, by way of example, in FIG. 1A, the inner element 104 and the outer sleeve 102 can be arranged at a distance apart, such that they do not slide against one another, for example. The outer sleeve 102 can be, for example, a cylinder, which can be converted into the shape of the outer sleeve 102, as illustrated herein, by means of two or more than two (e.g. three, four or five) coaxial boreholes of varying diameter, in which case the regions 106a, 106b, 108a, 108b, 110a can be provided by means of the coaxial boreholes.

According to various embodiments, the inside of the outer sleeve 102 can also have fewer steps than the number shown in FIG. 1A.

FIG. 1C shows a bearing arrangement 100 in a schematic cross-sectional view, an electrical contact structure 110 being provided between the inner element 104 and the outer sleeve 102 (e.g. in the region 110). Furthermore, a first bearing 118a can be inserted between the inner element 104 and the outer sleeve 102 (e.g. in the region 108a) in the axial direction 111 from the first end 100a (i.e. along the first axial direction 111a). Furthermore, a second bearing 118b can be inserted between the inner element 104 and the outer sleeve 102 (e.g. in the region 108b) in the axial direction 111 from the second end 100b (i.e. along the second axial direction 111b). Since, for example, the internal diameter of the outer sleeve 102 can be smaller in the region 110a than in the regions 108a, 108b, the outer sleeve 102 can have, for example, a protrusion 102v, by means of which the inserted bearings 108a, 108b can be positioned in the bearing arrangement 100. Therefore, the bearings 118a, 118b can be inserted, for example, without the latter making contact with the electrical contact structure 110.

The bearing arrangement 100 may furthermore have a first receiving region 106a at the first axial end portion of the bearing arrangement 100 for receiving at least one first seal or at least one first sealing element. The bearing arrangement 100 may furthermore have a second receiving region 106b at the second axial end portion of the bearing arrangement 100 for receiving at least one first seal or at least one first sealing element. As shown in FIG. 1C, the bearings 118a, 118b can be accessible from the axial direction 111, if no seals are inserted into the corresponding receiving regions 106a, 106b.

FIG. 1D shows a bearing arrangement 100 in a schematic cross-sectional view, an electrical contact structure 110, a first bearing 118a and a second bearing 118b being provided between the inner element 104 and the outer sleeve 102 (e.g. in the region 110), as described above. Furthermore, a first sealing element 116a can be inserted in a removable manner between the inner element 104 and the outer sleeve 102 (e.g. in the region 106a) in the axial direction 111 from the first end 100a (i.e. along the first axial direction 111a). Furthermore, a second sealing element 116b can be inserted in a removable manner between the inner element 104 and the outer sleeve 102 (e.g. in the region 106b) in the axial direction 111 from the second end 100b (i.e. along the second axial direction 111b). Since, for example, the internal diameter of the outer sleeve 102 can be smaller in the regions 108a, 108b than in the regions 106a, 106b, the outer sleeve 102 can have, for example, a further protrusion 102w, by means of which the inserted sealing elements 116a, 116b can be positioned in the bearing arrangement 100. Therefore, the sealing elements 116a, 116b can be inserted, for example, without the latter making contact with the mechanical bearings 118a, 118b.

By way of example, the sealing elements 116a, 116b can seal off the outer sleeve 102 with respect to the inner element 104. In this case, the first sealing element 116a can be a vacuum seal, such that, for example, the bearings 118a, 118b and/or the electrical contact structure 110 can be separated by a vacuum by means of the first sealing element 116a in the direction of the first end 100a of the bearing arrangement 100. Furthermore, the second sealing element 116b can be a fluid seal, such that, for example, the bearings 118a, 118b and/or the electrical contact structure 110 can be separated by a cooling fluid, which can partially flow through the bearing arrangement 100 for example, by means of the second sealing element 116b in the direction of the second end 100b of the bearing arrangement 100.

By way of example, the inner element 104 can be a hollow tube or have one or more boreholes or passage holes, such that cooling fluid can flow in the axial direction 111 through the inner element 104.

Analogously to the above description, FIG. 1E shows an alternative design for the arrangement of outer sleeve 102 and inner element 104. Here, by way of example, both the interior of the outer sleeve 102 and the exterior of the inner element 104 are designed in such a manner that the regions 106a, 106b, 108a, 108b, 110a, as described above, can be provided for receiving the electrical contact structure 110, the bearings 118a, 118b and/or the sealing elements 116a, 116b. Furthermore, as described above, the inner element 104 can be hollow or have a passage opening 104i.

Analogously to the above description, FIG. 1F shows an alternative design for the arrangement of outer sleeve 102 and inner element 104. Here, by way of example, the exterior of the inner element 104 is designed in such a manner that the regions 106a, 106b, 108a, 108b, 110a, as described above, can be provided for receiving the electrical contact structure 110, the bearings 118a, 118b and/or the sealing elements 116a, 116b. Furthermore, as described above, the inner element 104 can be hollow or have a passage opening 104i. In this case, the outer sleeve 102 can be a simple hollow cylinder 102.

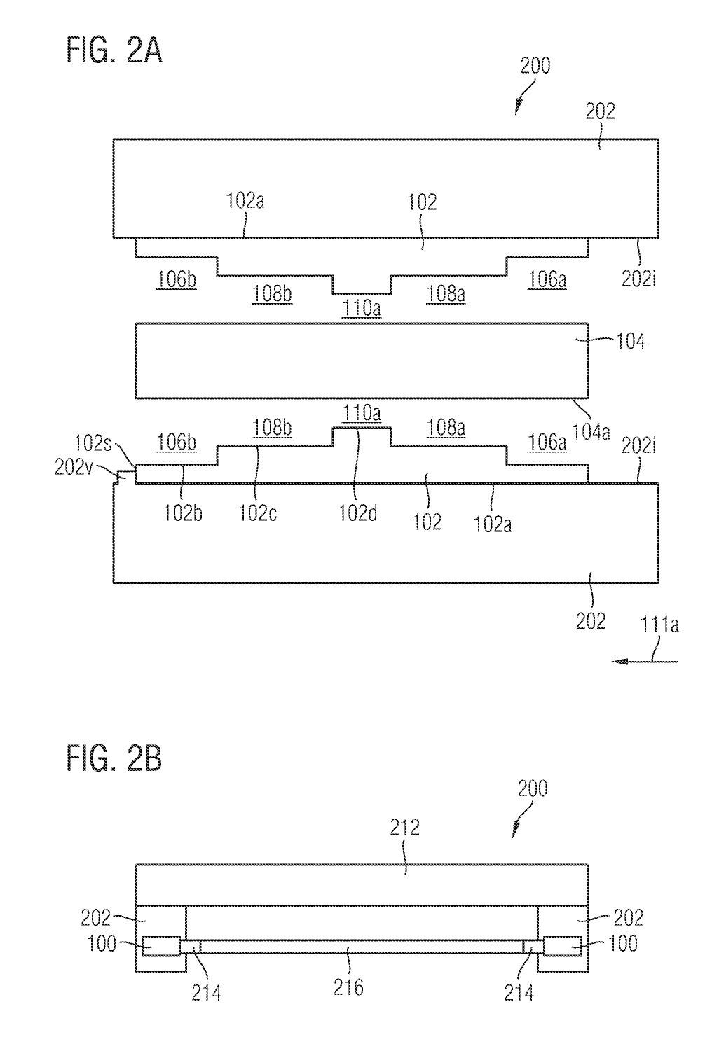

FIG. 2A shows an electrode arrangement 200 in a schematic cross-sectional view, wherein the electrode arrangement 200 has a housing 202, and wherein the housing 202 is designed in such a manner that the bearing arrangement 100 can be inserted into the housing 202 and can be removed from the housing, e.g. along the first axial direction 111a. When considered illustratively, the housing 202 can have a passage opening which is suitable for the outer sleeve 102 of the bearing arrangement 100, such that the bearing arrangement 100 is supported in the housing at a plurality of points or along at least one surface. By way of example, the outer surface 102a (lateral surface) of the outer sleeve 102 can adjoin or at least partially adjoin the inner surfaces 202i of the housing 202, in which case the inner surfaces 202i can be part of the passage opening or can define part of the passage opening.

By way of example, the housing 202 can be a mounting for holding an electrode in a vacuum chamber, e.g. what is termed an end block or a magnetron end block. Here, the housing 202 can be designed in such a manner that the electrode can be supplied with cooling water and/or electrical energy, the coupling between the electrode and the housing 202 being realized by means of the bearing arrangement 100.

According to various embodiments, the housing 202 of the electrode arrangement 200 can have a protrusion 202v at at least one point, such that the outer sleeve 102 of the inserted bearing arrangement 100 adjoins the protrusion 202v with an end face at the second end 100b of the bearing arrangement 100. Therefore, it is possible, for example, for the bearing arrangement 100 to be positioned, if it is inserted from the axial direction 111a into the housing 202. Illustratively, the outer sleeve 102 of the bearing arrangement 100 is not fixedly connected to the housing 202, i.e. the bearing arrangement 100 is inserted into the housing 202 in a removable manner or can be inserted into the housing 202 in a removable manner. In other words, the outer sleeve 102 of the bearing arrangement 100 is not formed in one piece with the housing 202. Therefore, for example, the bearing arrangement 100 can be replaced without it being necessary for the housing 202 to be disassembled. Furthermore, the outer sleeve 102 can be inserted into the housing in such a manner that it does not rotate or cannot rotate in relation to the housing when the inner element 104 rotates.

FIG. 2B shows an electrode arrangement 200 in a schematic cross-sectional view, wherein the electrode arrangement 200 has at least one housing 202 (e.g. two or else four housings 202), and wherein the at least one housing 202 is connected to a mounting 212 (e.g. a further component of the electrode arrangement 200). The electrode arrangement 200 can furthermore have a tubular electrode 216 (or for example two or more than two tubular electrodes 216), the at least one tubular electrode 216 being held by means of the at least one housing 202. Here, the electrode arrangement 200 can have at least one bearing arrangement 100 (e.g. in each case one per housing 202), by means of which the tubular electrode 216 is rotatably mounted.

By way of example, the electrode arrangement 200 can have coupling elements 214, by means of which the tubular electrode 216 can be coupled to the inner element 104 of the bearing arrangement 100.

Furthermore, the tubular electrode 216 can have a magnet arrangement inside the tubular electrode 216. Furthermore, the tubular electrode 216 can be designed in such a manner that the tubular electrode 216 can be cooled by means of a cooling fluid, which, for example, flows through the tubular electrode 216.

By way of example, the electrode arrangement 200 can be a magnetron arrangement 200, having: two end blocks 202 (e.g. in the case of a rotatable magnetron with one magnetron cathode) or four end blocks (e.g. in the case of a rotatable dual magnetron with two magnetron cathodes), wherein the end blocks are mechanically connected to a mounting 212 (e.g. to a magnetron cover or a further component of the magnetron arrangement 200). The magnetron arrangement 200 may furthermore have a magnetron cathode 216 or two magnetron cathodes 216, these being held appropriately by means of the end blocks 202. Here, the magnetron arrangement 200 can have one or more bearing arrangements 100 (e.g. in each case one per end block 202 or in each case one per electrode 216 in the electrode arrangement 200), by means of which the magnetron cathode or the plurality of magnetron cathodes can be mounted rotatably and/or electrically contact-connected. A magnetron cathode can have, for example, a magnet arrangement, by means of which a plasma can be generated outside the magnetron cathode. Furthermore, the magnetron cathode 216 can be designed in such a manner that it can be cooled from the inside by means of a cooling fluid.

The magnetron cathode 216 can be placed at or can be brought to cathode potential, for example, such that a sputtering process can be carried out in a vacuum chamber by means of the magnetron cathode.

Hereinbelow, various modifications and configurations of the bearing arrangement 100 and details in relation to the electrode arrangement 200 will be described, where the fundamental features and modes of operation described in relation to FIG. 1A to FIG. 1F, FIG. 2A and FIG. 2B can similarly be included. Furthermore, the features and modes of operation described below can be transferred analogously to the bearing arrangement 100 or electrode arrangement 200 described in FIG. 1A to FIG. 1F, FIG. 2A and FIG. 2B, or can be combined with the bearing arrangement 100 or electrode arrangement 200 described in FIG. 1A to FIG. 1F, FIG. 2A and FIG. 2B.

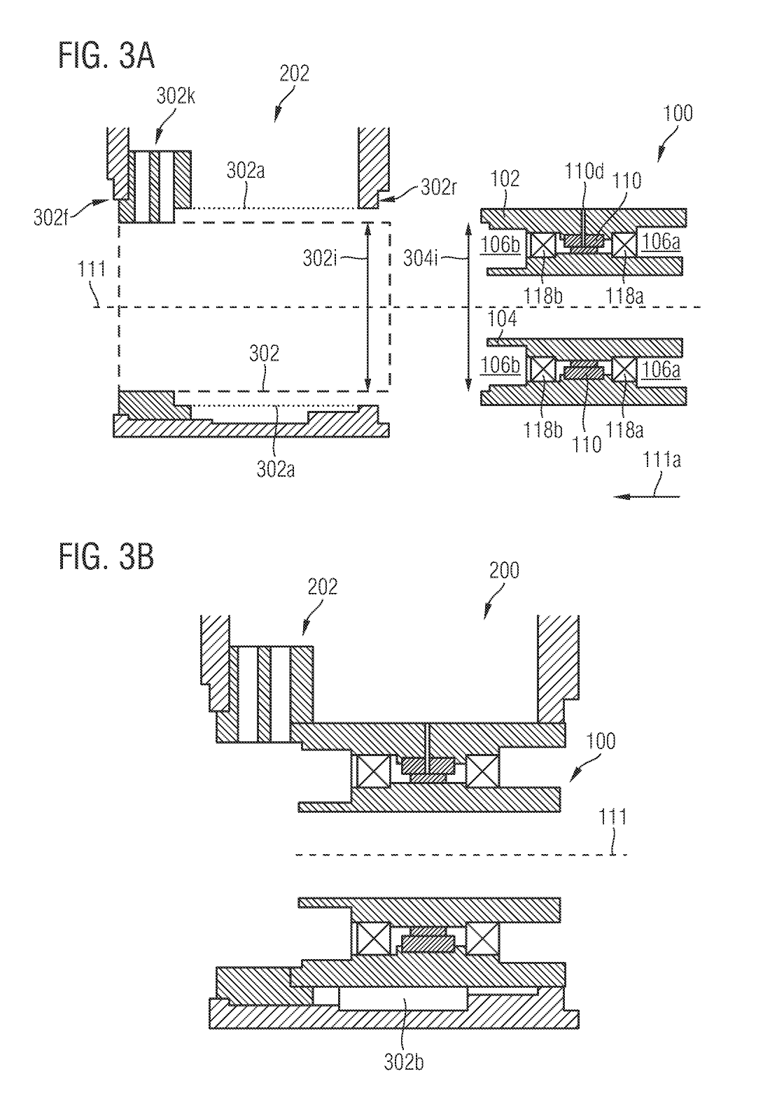

FIG. 3A shows in each case a housing 202 (on the left) and a bearing arrangement 100 (on the right) in a schematic cross-sectional view. By way of example, the housing 202 can have a passage opening 302, and can be designed in such a manner, for example having the region 302a (which can be part of the passage opening 302), that the bearing arrangement 100 can be inserted into the housing 202, for example along the axial direction 111a. Furthermore, the housing 202 can have a cooling water guide 302k, such that, for example, cooling water can be conducted through the housing 202 to the bearing arrangement 100 or further through the bearing arrangement 100 to an electrode coupled to the bearing arrangement 100. Furthermore, the housing 202 can have an annular flange receiving region 302r, such that an annular flange can be fastened to the housing 202. Furthermore, the housing 202 can have a flange receiving region 302f, such that a flange can be fastened to the housing 202.

According to various embodiments, the (e.g. smallest) diameter 302i of the passage opening of the housing 202 can be greater than or equal to the internal diameter 304i of the outer sleeve 102 of the bearing arrangement 100 in the region 106a, 106b (i.e. in the receiving region for the seals 116a, 116b), such that the seals 116a, 116b can be inserted through the housing 202 into the bearing arrangement 100.

Furthermore, the electrical contact structure 110 of the bearing arrangement 100 can be designed as a sliding contact. Here, the outer sleeve 102 can have an electrical leadthrough 110d in the region of the electrical contact structure 110, such that the electrical contact structure 110 can be contact-connected through the outer sleeve 102.

FIG. 3B shows the electrode arrangement 200 analogously to FIG. 3A, the bearing arrangement 100 being inserted into the housing 202 in a removable manner. The bearing arrangement 100 is supported, for example, at a plurality of points in the housing 202. According to various embodiments, a region 302b, in which the housing 202 has no mechanical contact with the bearing arrangement 100, can extend between the housing 202 and the inserted bearing arrangement 100.

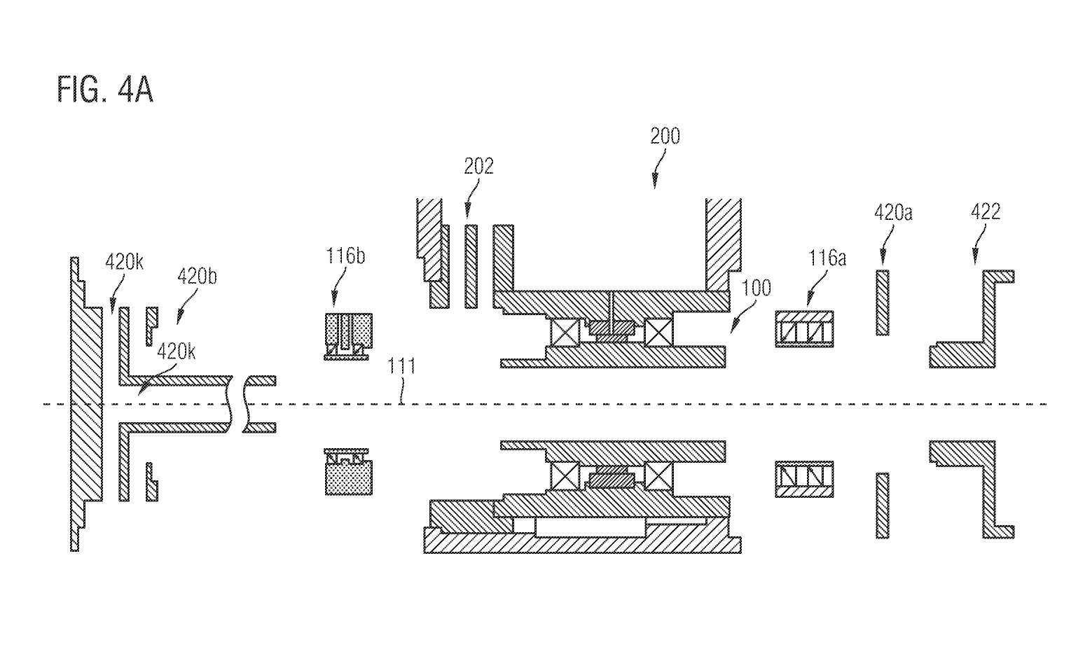

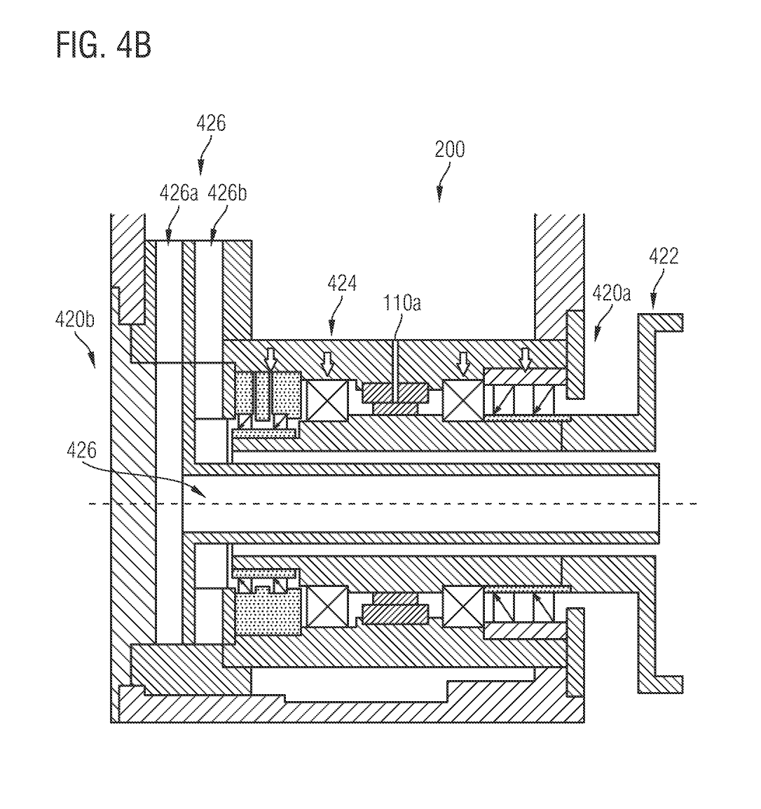

As is shown in FIG. 4A in a schematic exploded illustration (in cross section), the electrode arrangement 200 may furthermore have, in addition to the housing 202 and the inserted bearing arrangement 100, further components, which complete, for example, the electrode arrangement 200 in a modular form.

By way of example, the electrode arrangement 200 can have a first sealing element 116a, which can be inserted into the first receiving region 106a of the bearing arrangement 100. Illustratively, the first sealing element 116a can be inserted into the bearing arrangement 100 and/or removed from the bearing arrangement 100 without taking the bearing arrangement 100 out of the housing 202. The first sealing element 116a can be, for example, a vacuum seal or have a vacuum seal. Furthermore, the first sealing element 116a can also have a plurality of vacuum seals, which can be inserted in succession or at the same time into the bearing arrangement 100.

By way of example, the electrode arrangement 200 can have a second sealing element 116b, which can be inserted into the second receiving region 106b of the bearing arrangement 100. Illustratively, the second sealing element 116b can be inserted into the bearing arrangement 100 and/or removed from the bearing arrangement 100 without taking the bearing arrangement 100 out of the housing 202. The sealing element 116b can be, for example, a fluid seal or have a fluid seal. Furthermore, the second sealing element 116b can also have a plurality of fluid seals, which can be inserted in succession or at the same time into the bearing arrangement 100. A fluid seal can be understood to mean a seal which at least prevents the passage of a fluid, e.g. water.

Furthermore, the electrode arrangement 200 can have a flange ring 420a, which can be fastened, for example, to the housing 202, e.g. to the flange ring receiving region 302r of the housing 202 (cf. FIG. 3A). The flange ring 420a can be screwed, for example, to the housing 202. In other words, the flange ring 420a and the housing 202 of the electrode arrangement 200 can have a screwed connection.

By way of example, the flange ring 420a can have an external diameter which is greater than the external diameter 102d of the outer sleeve 102 of the bearing arrangement 100. Therefore, the first sealing element 116a and/or the bearing arrangement 100 can be fastened (fixed) to the housing 202 by means of the flange ring 420a. Furthermore, the first sealing element 116a and the bearing arrangement 100 can be fixed by means of the flange ring 420a such that the first sealing element 116a inserted into the bearing arrangement 100 seals off the first receiving region 106a of the bearing arrangement 100 in a vacuum-tight manner. Furthermore, the flange ring 420a can have a passage opening in the axial direction, it being possible for the internal diameter of the flange ring 420a to be greater than the external diameter 104d of the inner element 104. Therefore, part of the inner element 104 can be exposed when the flange ring 420a is assembled, e.g. the end face or the free end portion of the inner element 104, such that, for example, a coupling element 422 can be fastened to the inner element 104. By way of example, the coupling element 422 can be screwed to the inner element 104. By way of example, the coupling element 422 can be designed in such a manner that a tubular electrode can be fastened rotatably by means of the coupling element 422 to the bearing arrangement 100 and therefore to the housing 202.

Furthermore, the electrode arrangement 200 can have a flange 420b, which can be fastened, for example, to the housing 202, e.g. to the flange receiving region 302f of the housing 202 (cf. FIG. 3A). The flange 420b can be screwed, for example, to the housing 202. In other words, the flange 420b and the housing 202 of the electrode arrangement 200 can have a screwed connection.

According to various embodiments, the second sealing element 116b and/or the bearing arrangement 100 can be fastened (fixed) to the housing 202 by means of the flange 420b. Furthermore, the second sealing element 116b and the bearing arrangement 100 can be fixed by means of the flange 420b such that the second sealing element 116b inserted into the bearing arrangement 100 seals off the first receiving region 106b of the bearing arrangement 100 in a fluid-tight manner. Furthermore, the flange 420b can have a fluid guide 420k, such that cooling fluid can be conducted from the housing 202 to the inner element 104 and/or through the inner element 104 and/or out of the inner element 104 by means of the flange 420b. By way of example, the flange 420b can have a cooling fluid feed line 420k and a cooling fluid discharge line, such that an electrode coupled to the bearing arrangement 100 can be cooled by means of the assembled electrode arrangement 200 (cf. FIG. 4B). Furthermore, an electrode can be connected to the inner element 104 of the bearing arrangement 100 in an electrically conductive manner, such that the electrode can be brought to a predefined potential by means of the electrical contact structure 110, 110d of the bearing arrangement 100.

According to various embodiments, the electrical contact structure 110, 110d can be designed in such a manner that a current measuring several hundred amperes can be transferred to the inner element 104 and therefore to the electrode.

FIG. 4B shows the electrode arrangement 200 as is described, for example, with respect to FIG. 4A, wherein the seals 116a, 116b are inserted into the bearing arrangement 100 and are fixed by means of the flange 420b and the annular flange 420a, and wherein the coupling element is fastened to the inner element 104 of the bearing arrangement 100.

The inner element 104 can be mounted rotatably by means of the bearings 118a, 118b of the bearing arrangement 100, it being possible for the seals 116a, 116b to slip or slide on the inner element 104 when the inner element 104 rotates. The bearings of the bearing arrangement 100 can be, for example, roller bearings, ball bearings, rolling bearings or the like. Furthermore, the first bearing 118a and/or the second bearing 118b of the bearing arrangement 100 can have a plurality of bearings, e.g. a plurality of identical or different bearings pinned to one another.

As shown in FIG. 4B, the housing 202, the flange 420b and the bearing arrangement 100 can each be designed in such a manner that (in the assembled state) they make it possible for a cooling fluid guide 426 (e.g. for conducting cooling water) to be formed. By way of example, the housing 202 can have a cooling fluid inlet 426a for introducing the cooling fluid through the bearing arrangement 100 into an electrode coupled to the bearing arrangement 100. Furthermore, the housing 202 can have a cooling fluid outlet 426b for discharging the cooling fluid out of the electrode coupled to the bearing arrangement 100 through the bearing arrangement 100. By way of example, the electrode arrangement 200 makes it possible to implement a design in which the cooling fluid guide 426 can be realized in a space-saving manner. By way of example, the cooling fluid inlet 426a and the cooling fluid outlet 426b can be arranged alongside one another, e.g. at a small distance apart (at a distance apart of approximately 1 cm to approximately 10 cm).

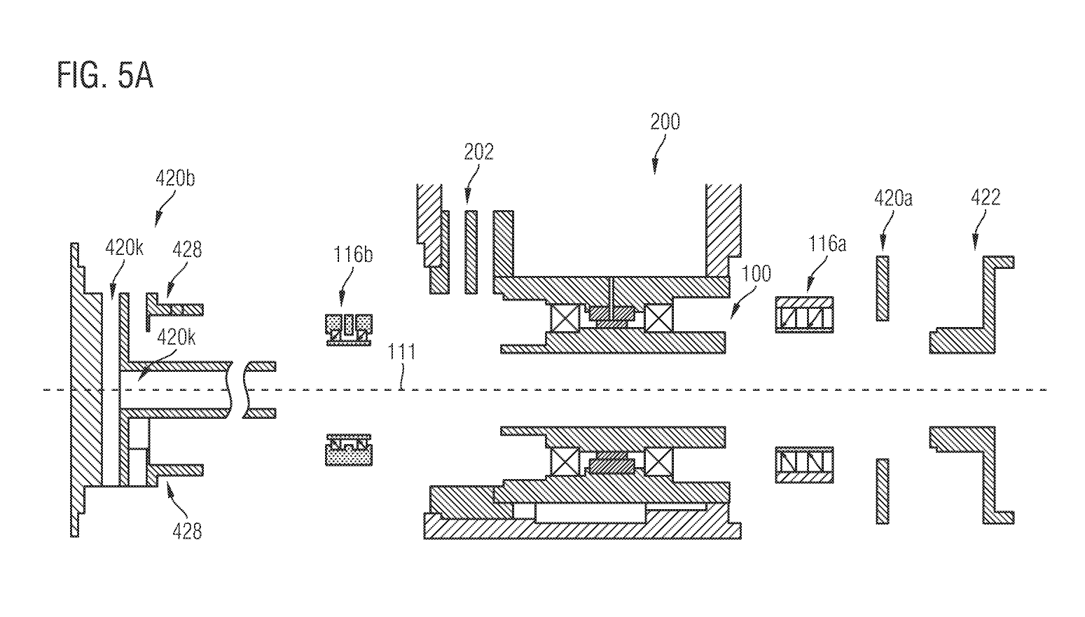

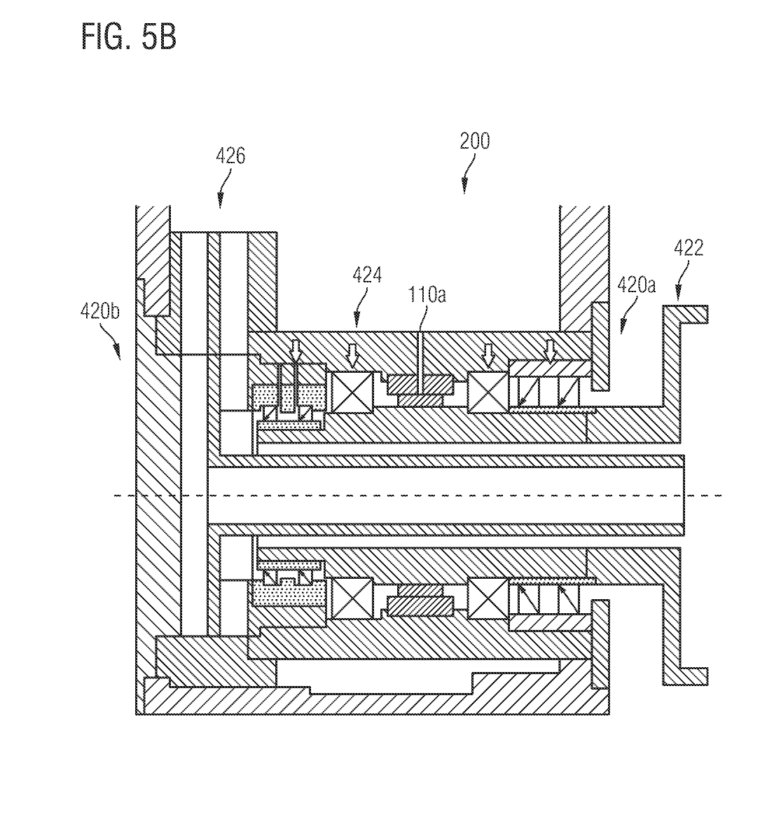

As is shown in FIG. 5A and FIG. 5B analogously to FIG. 4A and FIG. 4B, the flange 420b can also be designed in such a manner that it provides a part 428 of the second seal 116b, and therefore the second receiving region of the bearing arrangement 100 is sealed off (e.g. sealed off in a fluid-tight manner) by means of the second seal and by means of the flange 420b only when the electrode arrangement 200 has been assembled, cf. FIG. 5B. When assembled, the flange 420b fixes, for example, the second seal 116b in the bearing arrangement 100 and at the same time seals off the region 106b.

By way of example, the sealing off by means of the seals 116a, 116b can be understood to mean that a pressure difference or a partial pressure difference can be provided.

According to various embodiments, the outer sleeve 102 of the bearing arrangement 100 can have a lubricant feed line, such that, for example, the bearings 118a, 118b can be lubricated through the outer sleeve 102.

As is shown in FIG. 4B and FIG. 5B, the seals 116a, 116b can be replaced in a simple manner, for example. For this purpose, it is merely necessary to remove the flange 420b and/or the annular flange 420a and the coupling element 422. By way of example, the bearing arrangement 100 can remain in the housing 202 during the replacement of the seals 116a, 116b. The bearings 118a, 118b can also be replaced in the same manner.

According to various embodiments, the distance between the first bearing 118a and the second bearing 118b can lie in a range of several centimetres, e.g. in a range of approximately 5 cm to approximately 30 cm.

Furthermore, the bearing arrangement 100 can have a length (along the axial direction 111) in a range of approximately 10 cm to approximately 50 cm.

Furthermore, the bearing arrangement 100 can be designed in such a manner that the inner element 104 is electrically insulated from the outer sleeve 102. By way of example, the bearings (rolling bearings) may include or essentially consist of electrically insulating material or can have an electrically insulating design, e.g. also for avoiding electro-corrosion or electro-erosion (or sparking) on the bearing and/or on the running surfaces of the bearing. Furthermore, the cooling fluid used can be distilled water, and therefore there is no electrical short-circuit between the outer sleeve 102 and the inner element 104 via the cooling fluid.

According to various embodiments, the inner element 104 and the outer sleeve 102 can also have a conical or partially conical form, in which case the bearings 118a, 118b and the seals 116a, 116b then have to be adapted appropriately.

Furthermore, part of the flange 420b can extend into the tubular inner element 104, for example for conducting the cooling water in the inner element 104.

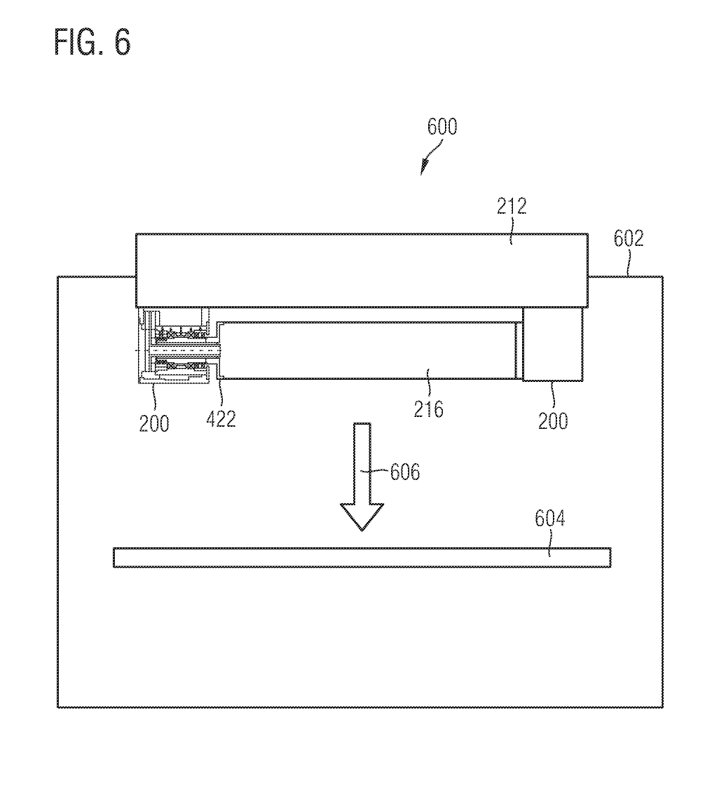

FIG. 6 schematically shows a coating arrangement 600 (e.g. a magnetron sputtering system) for coating 606 a substrate 604 in a vacuum chamber 602, wherein the coating arrangement 600 has a magnetron arrangement, it being possible for the magnetron arrangement to have the following: a mounting 212, e.g. a magnetron cover, an electrode arrangement 200 fastened to the mounting 212, as described above, and a magnetron cathode 216 (e.g. having a magnet arrangement and a cathode tube), the magnetron cathode 216 being mounted rotatably by means of the bearing arrangement 100 in the housing 202.

As is shown in FIG. 6, a magnetron cathode 216 or a plurality of magnetron cathodes 216 can be held in a vacuum chamber 602 by means of a plurality of housings 202, such that a sputtering process can be carried out for coating 606 the substrate 604 with atomized material of the magnetron cathode (or of the magnetron target).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A bearing arrangement for rotatably mounting an electrode, the bearing arrangement comprising:
an outer sleeve, which is insertable into a housing for mounting a rotatable electrode;
an inner element, which is received coaxially in the outer sleeve and is mounted by a first bearing and a second bearing so as to be rotatable in relation to the outer sleeve, wherein the bearings are spaced apart from one another in the axial direction; and
an electrically conductive contact structure, which is positioned alongside at least one of the first bearing or the second bearing and which makes electrical contact with the inner element.

2. The bearing arrangement of claim 1, further comprising:
a first receiving region, which is formed at a first axial end portion of the bearing arrangement between an inner circumference of the outer sleeve and an outer circumference of the inner element to receive a first sealing element.

3. The bearing arrangement of claim 1, further comprising:
a second receiving region, which is formed at a second axial end portion of the bearing arrangement between an inner circumference of the outer sleeve and an outer circumference of the inner element to receive a second sealing element.

4. The bearing arrangement of claim 1,
wherein a first distance between the outer circumference of the inner element and the inner circumference of the outer sleeve in the region between the first bearing and the second bearing is smaller than a second distance between the outer circumference of the inner element and the inner circumference of the outer sleeve in the region of at least one of the first bearing or the second bearing.

5. The bearing arrangement of claim 2,
wherein a third distance between the outer circumference of the inner element and the inner circumference of the outer sleeve in the region of at least one of the first receiving region or the second receiving region is greater than a second distance between the outer circumference of the inner element and the inner circumference of the outer sleeve in the region of at least one of the first bearing or of the second bearing.

6. The bearing arrangement of claim 1,
wherein the electrically conductive contact structure has at least one sliding contact, which slides on the outer circumference of the inner element.

7. The bearing arrangement of claim 1,
wherein the inner element has an axial passage opening.

8. The bearing arrangement of claim 1,
wherein the electrically conductive contact structure extends through the outer sleeve.

9. The bearing arrangement of claim 8,
wherein the outer sleeve is electrically insulated from the electrically conductive contact structure.

10. The bearing arrangement of claim 1,
wherein the first bearing and the second bearing comprise an electrically insulating material, so that the inner element is electrically insulated from the outer sleeve by the bearings.

11. An electrode arrangement, comprising:
a housing for mounting of a rotatable electrode, wherein the housing has a passage opening, which is formed to receive a bearing arrangement, the bearing arrangement comprising:
an outer sleeve, which is insertable into a housing for mounting a rotatable electrode;
an inner element, which is received coaxially in the outer sleeve and is mounted by a first bearing and a second bearing so as to be rotatable in relation to the outer sleeve, wherein the bearings are spaced apart from one another in the axial direction; and
an electrically conductive contact structure, which is positioned alongside at least one of the first bearing or the second bearing and which makes electrical contact with the inner element;
wherein the passage opening defines an axial direction and the housing is designed in such a manner that the bearing arrangement is introducible coaxially into the passage opening in a removable manner, such that the outer sleeve of the bearing arrangement is supported at least in certain portions on the housing.

12. The electrode arrangement of claim 11,
wherein the passage opening of the housing and the bearing arrangement are designed in such a manner that a first sealing element is insertable coaxially into the first receiving region of the bearing arrangement in a removable manner.

13. The electrode arrangement of claim 11,
wherein the passage opening of the housing and the bearing arrangement are designed in such a manner that a second sealing element is insertable coaxially into the second receiving region of the bearing arrangement in a removable manner.

14. The bearing electrode arrangement of claim 12,
wherein the first sealing element is a vacuum seal, by which the first receiving region between the outer sleeve and the inner element is sealed off in a vacuum-tight manner.

15. The bearing electrode arrangement of claim 13,
wherein the second sealing element is a fluid seal, by which the second receiving region between the outer sleeve and the inner element is sealed off in a fluid-tight manner.

16. The electrode arrangement of claim 11,
wherein the bearing arrangement and the second sealing element are fixable in relation to one another by means of a flange.

17. The electrode arrangement of claim 11,
wherein the bearing arrangement and the second sealing element are fixable on the housing by means of a flange.

18. The electrode arrangement of claim 11,
wherein the flange ring designed in such a manner that the free end portion of the inner element is accessible from the axial direction.

19. The electrode arrangement of claim 17,
wherein the flange has a cooling water guide, by which cooling water can be at least one of conducted through the flange towards the inner element or can be carried away from the inner element.

20. The electrode arrangement of claim 11, further comprising:
a coupling element configured to couple an electrode to the inner element, wherein the coupling element is fastened to a first axial end portion of the inner element.
